(19) United States
(12) Patent Application Publication
(10) Pub. No.: US 2025/0292809 A1
(43) Pub. Date: Sep. 18, 2025

(54) SEMICONDUCTOR DEVICE AND SEMICONDUCTOR STORAGE DEVICE

(71) Applicant: Kioxia Corporation, Tokyo (JP)

(72) Inventor: Tatsuro NISHIMOTO, Yokkaichi Mie (JP)

(21) Appl. No.: 19/078,150

(22) Filed: Mar. 12, 2025

(30) Foreign Application Priority Data
Mar. 15, 2024 (JP) 2024-041746

(51) Int. Cl. G11C 5/06; G11C 16/04; H01L 23/00; H10B 41/35; H10B 41/41; H10B 43/35; H10B 43/40; H10D 62/60

(52) U.S. Cl. CPC G11C 5/063; G11C 16/0483; H01L 24/08; H10B 41/35; H10B 41/41; H10B 43/35; H10B 43/40; H10D 62/60; H01L 2224/08145; H01L 2924/1438

(57) ABSTRACT

A semiconductor device includes a first substrate that includes a plurality of regions including a first region, a second region, and a third region between the first and second regions, a first transistor in the first region, a second transistor in the second region, a first trench in the third region, a first conductive layer that continuously covers the first transistor, the first trench, and the second transistor, and an impurity region that is adjacent to the first trench in the first substrate and includes carbon.

### CROSS-REFERENCE TO RELATED APPLICATIONS

This application is based upon and claims the benefit of priority from Japanese Patent Application No. 2024-041746, filed Mar. 15, 2024, the entire contents of which are incorporated herein by reference.

### FIELD

Embodiments disclosed herein relate to a semiconductor device and a semiconductor storage device.

### BACKGROUND

Semiconductor devices having a plurality of transistors provided on a semiconductor substrate are known. For example, semiconductor devices used in memory systems are required to have reduced footprint and increased packaging density as the memory systems are downsized. However, due to limitations of the manufacturing process for semiconductor devices, the reduction in size and the increase in packaging density may not be achievable. In particular, as the distance between adjacent transistors decreases, the leak current between the transistors may increase. To prevent the leak current, a technique of introducing an impurity into a part of the semiconductor substrate between the transistors to cause a shift in the threshold voltage of the transistors, is used.

### BRIEF DESCRIPTION OF THE DRAWINGS

FIG. 1 is a block diagram of a semiconductor device according to an embodiment.

FIG. 2 is a diagram for illustrating an equivalent circuit of a memory cell array of the semiconductor device.

FIG. 3 is a diagram for illustrating a circuit configuration of a sense amplifier module of the semiconductor device.

FIG. 4 is a diagram for illustrating a circuit configuration of a row decoder of the semiconductor device.

FIG. 5 is a cross-sectional view of the semiconductor device.

FIG. 6 is a plan view and a cross-sectional view of the semiconductor device.

FIG. 7 is a cross-sectional view of a PN junction region of the semiconductor device.

FIG. 8 is a cross-sectional view of the semiconductor device according to the embodiment.

FIG. 9 shows concentration profiles of an impurity implanted into an impurity region of the semiconductor device.

FIG. 10 shows concentration profiles of impurities implanted into the impurity region of the semiconductor device according to the embodiment.

FIG. 11 is a cross-sectional view of a semiconductor device according to a variation of the embodiment.

FIG. 12 is a cross-sectional view of a semiconductor device according to a variation of the embodiment.

FIG. 13 is a cross-sectional view for illustrating a manufacturing method for the semiconductor devices according to the embodiment and variations thereof.

FIG. 14 is a cross-sectional view for illustrating the manufacturing method for the semiconductor devices according to the embodiment and variations thereof.

FIG. 15 is a cross-sectional view for illustrating the manufacturing method for the semiconductor devices according to the embodiment and variations thereof.

FIG. 16 is a cross-sectional view for illustrating the manufacturing method for the semiconductor devices according to the embodiment and variations thereof.

FIG. 17 is a cross-sectional view for illustrating the manufacturing method for the semiconductor devices according to the embodiment and variations thereof.

FIG. 18 is a cross-sectional view for illustrating the manufacturing method for the semiconductor devices according to the embodiment and variations thereof.

FIG. 19 is a cross-sectional view of a semiconductor device according to another embodiment.

FIG. 20 is a cross-sectional view of a semiconductor device according to another embodiment.

### DETAILED DESCRIPTION

Embodiments of this disclosure provide a semiconductor device that has a good junction withstand voltage and reduces a leak current between adjacent transistors.

In general, according to one embodiment, a semiconductor device comprises a first substrate that includes a plurality of regions including a first region, a second region, and a third region between the first and second regions; a first transistor in the first region; a second transistor in the second region; a first trench in the third region; a first conductive layer that continuously covers the first transistor, the first trench, and the second transistor; and an impurity region that is adjacent to the first trench in the first substrate and includes carbon.

In the following, semiconductor devices according to embodiments will be specifically described with reference to the drawings. In the following description, elements having the same functions or configurations are denoted by the same reference numerals and will be repeatedly described as needed. The embodiments described below are examples of devices or methods that implement the technical concepts of the embodiments. The technical concepts of the embodiments are not limited to the materials, shapes, structures, arrangements, and the like of components described below. The technical concepts of the embodiments include various modifications to the claims.

### 1. First Embodiment

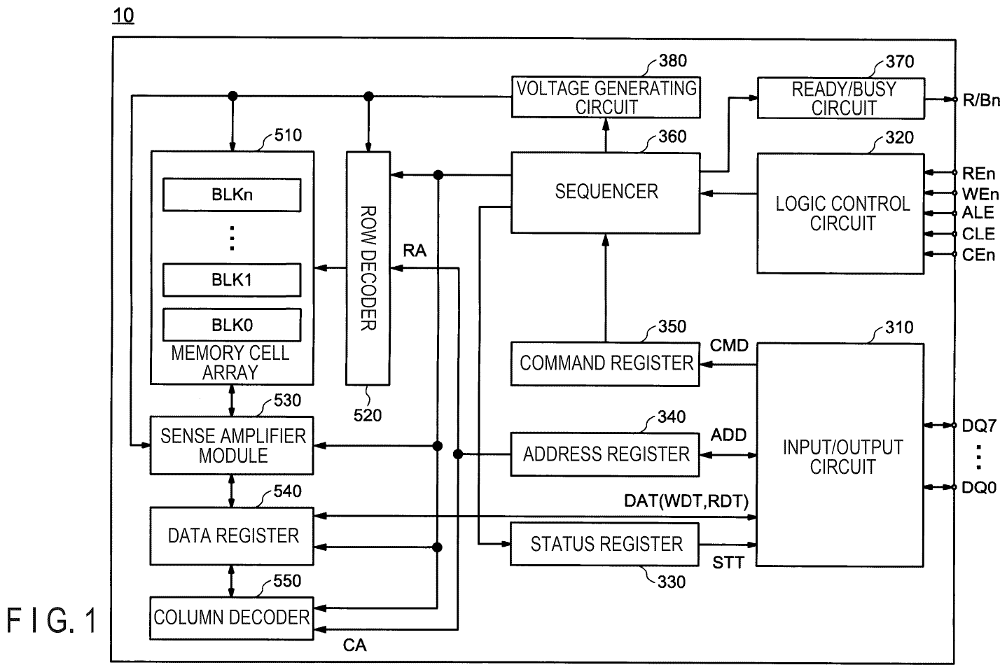

With reference to FIGS. 1 to 10, a semiconductor device according to a first embodiment will be described.

### 1-1. General Configuration of Semiconductor Device

FIG. 1 is a block diagram of a semiconductor device 10 according to this embodiment. As shown in FIG. 1, the semiconductor device 10 includes an input/output circuit 310, a logic control circuit 320, a status register 330, an address register 340, a command register 350, a sequencer 360, a ready/busy circuit 370, a voltage generating circuit 380, a memory cell array 510, a row decoder 520, a sense amplifier module 530, a data register 540, and a column decoder 550.

The input/output circuit 310 controls input and output of a signal DQ to and from an external device (not shown), such as a memory controller, which controls the semiconductor device 10. The signal DQ is an 8-bit signal, such as DQ0 to DQ7. The input/output circuit 310 includes an input circuit and an output circuit (not shown).

The input circuit transmits data DAT such as write data WDT received from the external device to the data register 540, transmits an address ADD to the address register 340, and transmits a command CMD to the command register 350.

The output circuit transmits status information STT received from the status register 330, data DAT such as read data RDT received from the data register 540, and an address ADD received from the address register 340 to the external device.

The logic control circuit 320 receives a chip enable signal CEn, a command latch enable signal CLE, an address latch enable signal ALE, a write enable signal WEn, and a read enable signal REn from the external device, for example. The logic control circuit 320 controls the input/output circuit 310 and the sequencer 360 in accordance with the received signals.

The status register 330 temporarily retains status information STT in a data write operation, a data read operation or a data erasure operation, for example, and notifies the external device of whether the operation has normally ended via the input/output circuit 310.

The address register 340 temporarily retains an address ADD received from the external device via the input/output circuit 310. The address register 340 transfers a row address RA to the row decoder 520 and transfers a column address CA to the column decoder 550.

The command register 350 temporarily retains a command CMD received from the external device via the input/output circuit 310, and transfers the command CMD to the sequencer 360.

The sequencer 360 controls the operation of the semiconductor device 10. More specifically, for example, the sequencer 360 controls the status register 330, the ready/busy circuit 370, the voltage generating circuit 380, the row decoder 520, the sense amplifier module 530, the data register 540, the column decoder 550, or the like in accordance with the command CMD retained in the command register 350 and performs the write operation, the read operation, the erasure operation, or the like.

The ready/busy circuit 370 transmits a ready/busy signal R/Bn to the external device in accordance with the operational status of the sequencer 360.

The voltage generating circuit 380 generates a voltage required for the write operation, the read operation or the erasure operation under the control of the sequencer 360, and applies the generated voltage to the memory cell array 510, the row decoder 520, the sense amplifier module 530, or the like. The row decoder 520 and the sense amplifier module 530 apply the voltage applied by the voltage generating circuit 380 to a memory cell in the memory cell array 510.

The memory cell array 510 includes a plurality of blocks BLK (BLK0 to BLKn) where n denotes an integer equal to or greater than 2. The block BLK is a set of a plurality of memory cells associated with a bit line and a word line. For example, the block BLK is a unit of data erasure. The memory cell is a charge retention transistor, for example, and stores data based on the retained charge in a nonvolatile manner. Having such memory cells, the semiconductor device 10 serves as a NAND-type nonvolatile memory, for example.

The row decoder 520 decodes the row address RA. The row decoder 520 selects any of the plurality of blocks BLK based on the result of the decoding. The row decoder 520 applies a voltage required for the write operation, the read operation or the erasure operation to the block BLK.

In the read operation, the sense amplifier module 530 senses or detects data from the memory cell array 510. In the read operation, the sense amplifier module 530 transmits the read data RDT to the data register 540. In the write operation, the sense amplifier module 530 transmits write data WDT to the memory cell array 510.

As described in detail later, the data register 540 includes a plurality of latch circuits. The latch circuit retains the write data WDT and the read data RDT. For example, in the write operation, the data register 540 temporarily retains the write data WDT received from the input/output circuit 310, and transmits the write data WDT to the sense amplifier module 530. In the read operation, the data register 540 temporarily retains the read data RDT received from the sense amplifier module 530, and transmits the read data RDT to the input/output circuit 310.

The column decoder 550 decodes the column address CA in the write operation, the read operation or the erasure operation, and selects a latch circuit in the data register 540 in accordance with the result of the decoding.

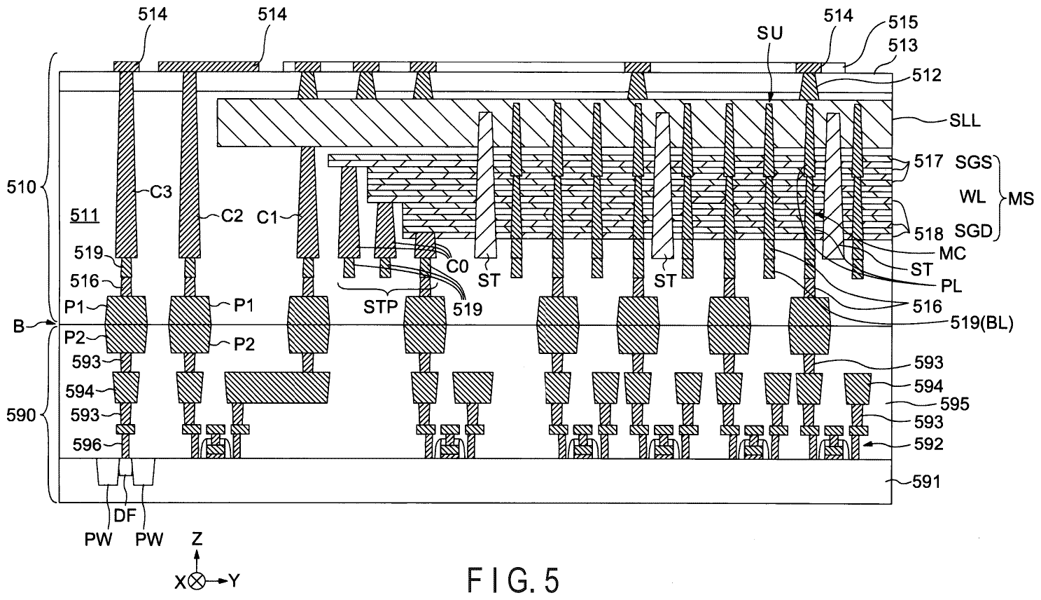

Note that a group of circuits arranged around the memory cell array 510 may be referred to as a peripheral circuit 590 (see FIG. 5). The peripheral circuit 590 includes at least the row decoder 520, the sense amplifier module 530, the data register 540 and the column decoder 550. The status register 330, the address register 340, the command register 350 and the sequencer 360 may also be included in the peripheral circuit 590. Furthermore, the input/output circuit 310, the logic control circuit 320, the ready/busy circuit 370 and the voltage generating circuit 380 may also be included in the peripheral circuit 590.

Thus, the semiconductor device 10 includes the memory cell array 510 including a plurality of memory cells and the peripheral circuit 590 that drives the plurality of memory cells.

### 1-2. Configuration of Memory Cell Array

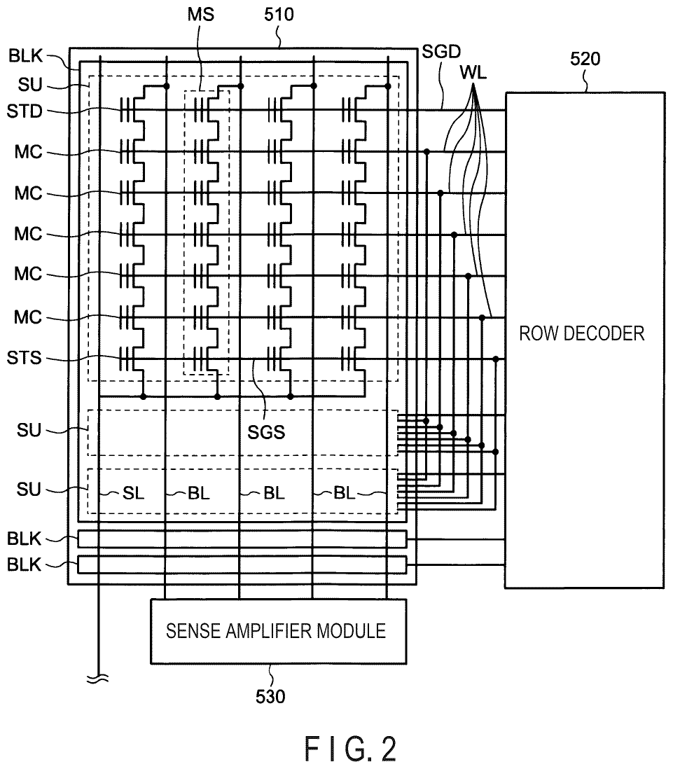

A circuit configuration of the memory cell array 510 will be described with reference to FIG. 2. FIG. 2 is a diagram for illustrating an equivalent circuit of the memory cell array 510 of the semiconductor device 10 according to this embodiment.

The memory cell array 510 includes a plurality of blocks BLK as described above. The plurality of blocks BLK each include a plurality of string units SU. The plurality of string units SU each include a plurality of memory strings MS. One end of each of the plurality of memory strings MS is connected to the peripheral circuit 590 such as the sense amplifier module 530 via a bit line BL. The other ends of the plurality of memory strings MS are connected to the peripheral circuit 590 via a common source line SL.

The memory string MS is provided between the bit line BL and the source line SL. The memory string MS includes a drain selection transistor STD, a plurality of memory cells MC and a source selection transistor STS, which are connected in series between the bit line BL and the source line SL. In the following, the drain selection transistor STD and the source selection transistor STS may be referred to simply as a selection transistor (STD, STS).

The memory cell MC is a field effect transistor (FET) including a charge storage layer in a gate insulating later, for example. The threshold voltage of the memory cell MC varies with the amount of charge retained in the charge storage layer. By providing one or more threshold voltages, the memory cell MC can store data of one or more bits. The plurality of memory cells MC included in one memory string MS each have a gate terminal connected to a word line WL. A plurality of (or all) memory strings MS in one block BLK are commonly connected to each word line WL.

The selection transistor (STD, STS) is a field effect transistor, for example. Gate terminals of the selection transistors (STD, STS) are connected to selection gate lines (SGD, SGS), respectively. The selection gate line SGD connected to the drain selection transistor STD is provided for each string unit SU and commonly connected to a plurality of (or all) memory strings MS in one string unit SU. The selection gate line SGS connected to the source selection transistor STS is commonly connected to a plurality of (or all) memory strings MS in one block BLK.

The word lines WL and the selection gate lines (SGD, SGS) are each connected to the peripheral circuit 590 such as the row decoder 520 at one end thereof.

### 1-3. Configuration of Sense Amplifier Module

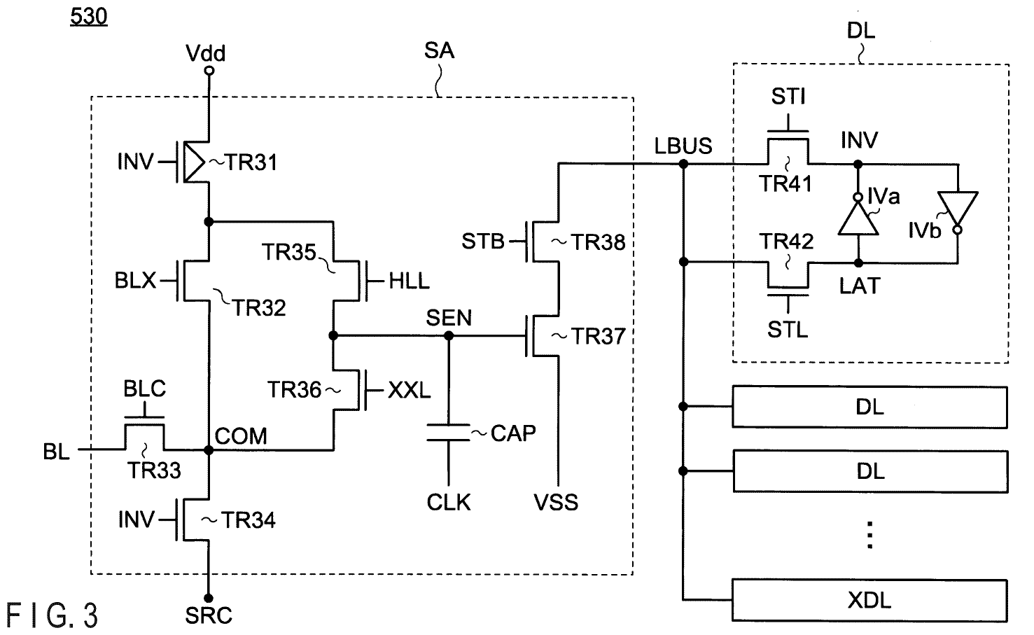

A circuit configuration of the sense amplifier module 530 will be described with reference to FIG. 3. FIG. 3 is a diagram for illustrating a circuit configuration of the sense amplifier module of the semiconductor device according to this embodiment. As shown in FIG. 3, the sense amplifier module 530 includes a sense amplifier circuit SA, a plurality of latch circuits DL, and a latch circuit XDL.

One sense amplifier circuit SA is provided for one or more bit lines BL. In the read operation, for example, the sense amplifier circuit SA senses data read on an associated bit line BL and determines whether the read data is 0 or 1.

The plurality of latch circuits DL and the latch circuit XDL are associated with a plurality of sense amplifier circuits SA. That is, a plurality of latch circuits DL and a latch circuit XDL are provided for each bit line BL, and a plurality of latch circuits DL are provided for each sense amplifier circuit SA. The number of latch circuits DL is determined based on the bit line BL for data that can be retained by one memory cell MC. The plurality of latch circuits DL and the latch circuit XDL temporarily retain data associated with the associated bit line BL.

FIG. 3 shows one sense amplifier circuit SA in the sense amplifier module 530 and a plurality of latch circuits DL and a latch circuit XDL associated with the sense amplifier circuit SA. Note that a plurality of control signals supplied to the sense amplifier circuit SA or the like are controlled by the sequencer 360.

As shown in FIG. 3, the sense amplifier circuit SA includes transistors TR31 to TR38 and a capacitor CAP. The transistor TR31 is a low withstand voltage P-channel metal oxide semiconductor (MOS) transistor. The transistors TR32 to TR38 are low withstand voltage N-channel MOS transistors.

Low withstand voltage CMOS transistors including the low withstand voltage P-channel MOS transistor and the low withstand voltage N-channel MOS transistor are transistors to which a relatively low voltage is applied, and are referred to also as low voltage (LV) or very low voltage (VLV) MOS transistors. On the other hand, high withstand voltage CMOS transistors including the high withstand voltage P-channel MOS transistor and high withstand voltage N-channel MOS transistor described later are transistors to which a relatively high voltage is applied and are referred to also as high voltage (HV) MOS transistors. Here, the relatively high voltage means a voltage higher than the voltage applied to the low withstand voltage CMOS transistors, for example.

A first terminal of the transistor TR31 is connected to a power supply line to which a power supply voltage Vdd is applied, and a gate terminal of the transistor TR31 is connected to a node INV. A first terminal of the transistor TR32 is connected to a second terminal of the transistor TR31, a second terminal of the transistor TR32 is connected to a node COM, and a control signal BLX is input to a gate terminal of the transistor TR32. A first terminal of the transistor TR33 is connected to the node COM, a second terminal of the transistor TR33 is connected to the associated bit line BL via a high withstand voltage N-channel MOS transistor (not shown), and a control signal BLC is input to a gate terminal of the transistor TR33.

A first terminal of the transistor TR34 is connected to the node COM, a second terminal of the transistor TR34 is connected to a node SRC, and a gate terminal of the transistor TR34 is connected to the node INV.

A first terminal of the transistor TR35 is connected to the second terminal of the transistor TR31, a second terminal of the transistor TR35 is connected to a node SEN, and a control signal HLL is input to a gate terminal of the transistor TR35. A first terminal of the transistor TR36 is connected to the node SEN, a second terminal of the transistor TR36 is connected to the node COM, and a control signal XXL is input to a gate terminal of the transistor TR36.

A ground voltage VSS is applied to a first terminal of the transistor TR37, and a gate terminal of the transistor TR37 is connected to the node SEN. A first terminal of the transistor TR38 is connected to a second terminal of the transistor TR37, a second terminal of the transistor TR38 is connected to a bus LBUS, and a control signal STB is input to a gate terminal of the transistor TR38. A first terminal of the capacitor CAP is connected to the node SEN, and a clock signal CLK is input to a second terminal of the capacitor CAP.

The latch circuit DL includes inverters IVa and IVb and transistors TR41 and TR42. As described above, the latch circuit DL is provided in the sense amplifier module 530. The transistors TR41 and TR42 are low withstand voltage N-channel MOS transistors. In the following, the transistors TR41 and TR42 included in the latch circuit DL may be referred to simply as transistors TR.

The inverter IVa is configured to have an input terminal connected to a node LAT and an output terminal connected to the node INV. The inverter IVb is configured to have an input terminal connected to the node INV and an output terminal connected to the node LAT.

The transistor TR41 is configured to have a first terminal connected to the node INV, a second terminal connected to the bus LBUS and a gate terminal to which a control signal STI is input. The transistor TR42 is configured to have a first terminal connected to the node LAT, a second terminal connected to the bus LBUS and a gate terminal to which a control signal STL is input.

The latch circuit XDL has substantially the same configuration as the latch circuit DL, for example, and is connected to the bus LBUS so that the latch circuit XDL can transmit and receive data to and from the sense amplifier circuit SA and the latch circuit DL. The latch circuit XDL is connected to the input/output circuit 310 described above and is used for data input/output between the sense amplifier circuit SA and the input/output circuit 310.

The latch circuit XDL is also used for a cache operation of the semiconductor device 10. That is, even when all the latch circuits DL associated with the sense amplifier circuit SA are in use, the semiconductor device 10 can accept data from the outside if there is an available latch circuit XDL.

Next, an operation of the sense amplifier circuit SA having the configuration described above will be briefly described. When a data write operation is performed on a memory cell MC, charges are injected to the memory cell MC to raise a threshold voltage of the memory cell MC. In this case, the node INV of the latch circuit DL is controlled to be an “H” level (data “1” is stored, for example). As a result, the transistor TR34 having the gate terminal connected to the node INV is turned on, and a voltage (0 V, for example) applied to the node SRC is applied to the bit line BL. On the other hand, when no charges are injected to the memory cell MC and the threshold voltage of the memory cell MC does not change, the node INV of the latch circuit DL is controlled to be an “L” level (data “O” is stored, for example). As a result, the transistor TR31 having the gate terminal connected to the node INV is turned on, and a predetermined positive voltage (i.e., the power supply voltage Vdd) is applied to the bit line BL.

When a read operation is performed, the node INV is controlled to be the “L” level, and the transistor TR31 is turned on. Furthermore, the bit line BL is pre-charged by the transistor TR31 via the transistors TR41 and TR42. The transistor TR35 is also turned on, and the node SEN is charged to a predetermined potential.

After that, the transistor TR35 is turned off, and the control signal XXL is controlled to be the “H” level, and thereby the transistor TR36 is turned on. As a result, if the associated memory cell MC is in the on state, the potential of the node SEN decreases, and the transistor TR37 is turned off. On the other hand, if the associated memory cell MC is in the off state, the potential of the node SEN is maintained at the “H” level, and the transistor TR37 is turned on.

After that, the transistor TR38 is turned on by the control signal STB, and a potential according to the on/off state of the transistor TR37 is read out to the bus LBUS and retained by the latch circuit DL.

The circuit configuration of the sense amplifier circuit SA, the plurality of latch circuits DL and the latch circuit XDL shown in FIG. 3 are just an example, and other configurations are possible. That is, the number and types of the transistors TR included in the sense amplifier circuit SA and the latch circuits DL and XDL may be different from those in the configuration described above. For example, the sense amplifier circuit SA or the latch circuit DL or XDL may include a high withstand voltage P-channel MOS transistor, a high withstand voltage N-channel MOS transistor, or the like.

### 1-4. Circuit Configuration of Row Decoder

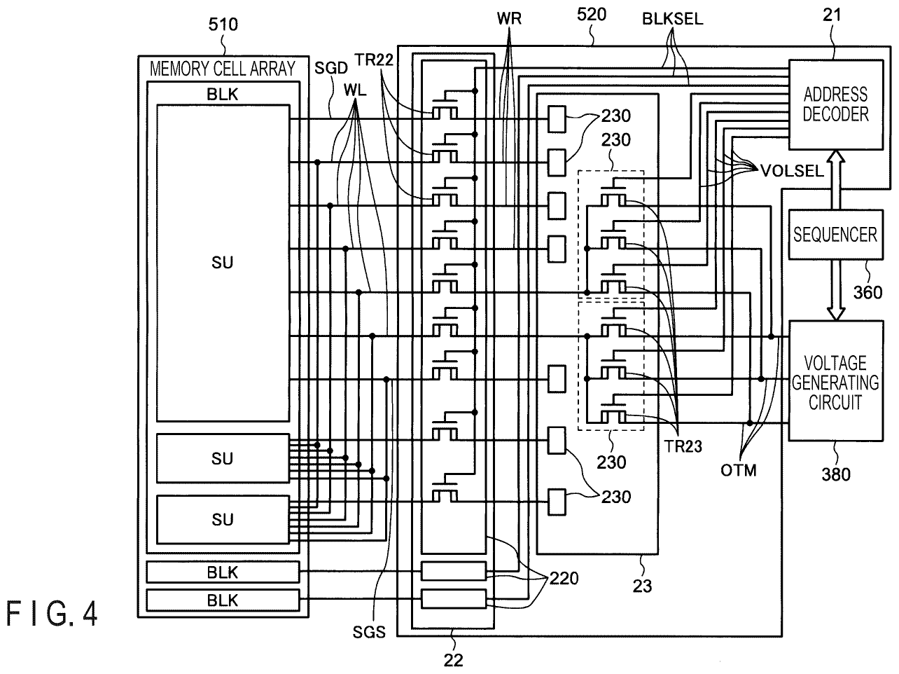

A circuit configuration of the row decoder 520 will be described with reference to FIG. 4. FIG. 4 is a diagram for illustrating a circuit configuration of the row decoder of the semiconductor device according to this embodiment. As shown in FIG. 4, the row decoder 520 includes an address decoder 21, a block selection circuit 22, and a voltage selection circuit 23.

The address decoder 21 includes a plurality of block selection lines BLKSEL and a plurality of voltage selection lines VOLSEL. The address decoder 21 refers to address data in the address register 340 included in the peripheral circuit 590 described above in accordance with a control signal from the sequencer 360, for example.

The address decoder 21 decodes the address data referred to, controls transistors TR22 and TR23 associated with the address data to be the on state, and controls the other transistors TR22 and TR23 to be the off state. The transistors TR22 and TR23 are transistors included in the block selection circuit 22 and the voltage selection circuit 23, respectively, which will be described later.

The address decoder 21 controls block selection lines BLKSEL and voltage selection lines VOLSEL associated with the address data to be the “H” level and controls the other block selection lines BLKSEL and voltage selection lines VOLSEL to be the “L” level, for example. Note that the example described here is an example in the case where N-type transistors are used in the block selection circuit 22 and the voltage selection circuit 23. When P-type transistors are used in the block selection circuit 22 and the voltage selection circuit 23, the voltages applied to the wires are inverted.

In the example in FIG. 4, in the address decoder 21, one block selection line BLKSEL is provided for each block BLK included in the memory cell array 510. However, this configuration can be modified as required. For example, each block selection line BLKSEL may be provided for two or more blocks BLK.

The block selection circuit 22 includes a plurality of block selection units 220. Each of the plurality of block selection units 220 corresponds to a block BLK. The plurality of block selection units 220 each include a plurality of transistors TR22 that correspond to the word lines WL and the selection gate lines (SGD, SGS). The transistor TR22 is a transistor that selects a word line WL associated with a relevant memory cell MC, and the transistor TR22 may be referred to as a “word line selecting transistor.”

The transistor TR22 is a high withstand voltage N-channel MOS transistor and functions as a block driving transistor. A drain terminal of each transistor TR22 is electrically connected to an associated word line WL or selection gate line (SGD, SGS). A source terminal of each transistor TR22 is electrically connected to a voltage output terminal OTM via a wire WR and the voltage selection circuit 23. The voltage output terminal OTM is electrically connected to the voltage generating circuit 380. Gate terminals of the transistors TR22 in each block selection unit 220 are commonly connected to an associated block selection line BLKSEL.

Although not shown, the block selection circuit 22 includes a plurality of transistors connected between the selection gate lines (SGD, SGS) and a ground voltage supply terminal. The plurality of transistors are high withstand voltage CMOS transistors. The plurality of transistors allow conduction between the selection gate lines (SGD, SGS) in the blocks BLK that are not selected in the memory cell array 510 and the ground voltage supply terminal. Note that the word lines WL included in the blocks BLK that are not selected are in a floating state.

The voltage selection circuit 23 includes a plurality of voltage selection units 230 associated with the word lines WL and the selection gate lines (SGD, SGS). The plurality of voltage selection units 230 each include a plurality of transistors TR23.

The transistor TR23 is a high withstand voltage N-channel MOS transistor and functions as a voltage selecting transistor. A drain terminal of each transistor TR23 is electrically connected to an associated word line or selection gate line (SGD, SGS) via a wire WR and the block selection circuit 22. A source terminal of each transistor TR23 is electrically connected to an associated voltage output terminal OTM. A gate terminal of each transistor TR23 is connected to an associated voltage selection line VOLSEL.

As described above, the row decoder 520 belonging to the peripheral circuit 590 includes a plurality of transistors TR22, TR23, and the like. However, the circuit configuration of the row decoder 520 shown in FIG. 4 is just an example, and the number and types of the transistors TR22, TR23, and the like included in the row decoder 520 are not limited to those in the example described above.

### 1-5. Cross-Sectional Structure of Semiconductor Device 10

A cross-sectional structure of the semiconductor device 10 will be described with reference to FIG. 5. FIG. 5 is a cross-sectional view of the semiconductor device 10 according to this embodiment. As shown in FIG. 5, a principal surface of a substrate 591 of the peripheral circuit 590 extends in X-direction and Y-direction. The direction perpendicular to each of X-direction and Y-direction is Z-direction. In the following description, Z-direction may be referred to as upper or upward, and the opposite direction may be referred to as lower or downward.

As shown in FIG. 5, the memory cell array 510 and the peripheral circuit 590 are bonded to each other at an interface B. The memory cell array 510 has an interface electrode P1 on one side of the interface B. The peripheral circuit 590 has an interface electrode P2 on the other side of the interface B. The circuit provided in the memory cell array 510 is electrically connected to the circuit provided in the peripheral circuit 590 via the interface electrodes P1 and P2.

The peripheral circuit 590 includes the substrate 591, a processing circuit 592, a via 593, wiring 594, an insulating layer 595, and the interface electrode P2.

The substrate 591 is a semiconductor substrate. As the semiconductor substrate, a silicon substrate is used. However, as the semiconductor substrate, a silicon on insulator (SOI) substrate, a compound semiconductor substrate, or the like may be used.

The processing circuit 592 includes a transistor provided on the substrate 591. For example, the processing circuit 592 includes the row decoder 520 and the sense amplifier module 530. The processing circuit 592 includes a capacitive element and a resistive element, in addition to the transistor.

The via 593 is a wire that is provided in an opening in the insulating layer 595 and extends in Z-direction. The via 593 electrically connects the processing circuit 592 and the wiring 594 to each other. Although FIG. 5 shows only one layer of wiring 594, a plurality of layers of wiring 594 are provided with the insulating layers 595 interposed therebetween in Z-direction, and layers of wiring 594 adjacent to each other in Z-direction are connected to each other by vias 593. Similarly, the interface electrode P2 and the wiring 594 adjacent thereto in Z-direction are also connected by the via 593.

At an end of the peripheral circuit 590, an N+-diffused region DF is provided, and P wells PW are provided on the opposite sides of the N+-diffused region DF. The N+-diffused region DF is connected to the interface electrode P1 of the memory cell array 510 via the via 593 provided in the processing circuit 592, the wiring 594, a contact 596, and the interface electrode P2.

The memory cell array 510 includes a memory string MS, a slit ST, a source layer SLL, insulating layers 511, 513, 515 and 518, a contact C1, vias C2 and C3, wires 514 and 519, vias 512 and 516, and a conductive layer 517.

The memory string MS includes a pillar PL, a plurality of conductive layers 517 and a plurality of insulating layers 518. A plurality of pillars PL extend along Z-direction. In the example in FIG. 5, two pillars PL are stacked in the Z-direction. An arrangement including the stacked pillars PL and a plurality of memory strings MS is referred to as a string unit SU.

The pillar includes a core layer, a semiconductor layer, insulating layers, and a charge storage layer. The core layer is a core of the pillar PL and is an insulator. The semiconductor layer is provided around the core layer, an insulating layer is provided around the semiconductor layer, the charge storage layer is provided around the insulating layer, and an insulating layer is provided around the charge storage layer. A plurality of conductive layers 517 and a plurality of insulating layer 518 are alternately stacked in Z-direction. The plurality of conductive layers 517 are provided to surround the insulating layers on the outside of the pillars PL. A part formed by each of the plurality of conductive layers 517 and the pillar PL to which the conductive layer is opposed constitutes a memory cell MC. In other words, the conductive layer 517 functions as the gate electrode of the memory cell MC.

The plurality of conductive layers 517 extend in Y-direction. The plurality of conductive layers 517 function as the word lines WL and the selection gate lines (SGD, SGS). At ends of the plurality of conductive layers 517, a step part STP is provided. The step configuration of the step part STP allows each of the plurality of conductive layers 517 to be exposed from the conductive layer 517 below the conductive layer and connected to the wire 519 via a via C0.

The semiconductor layer of the pillar PL is connected to the via 516 and the source layer SLL. The via 516 is connected to the wire 519 that functions as the bit line BL. The bit line BL extends in X-direction. The bit line BL is connected to the interface electrode P1 via the via 516.

The via 512, the insulating layer 513, the wire 514, and the insulating layer 515 are provided on the source layer SLL. The wire 514 provided at a position corresponding to the N+-diffused region DF of the peripheral circuit 590 is connected to the interface electrode P2 of the peripheral circuit 590 via the via C3, the wire 519, the via 516, and the interface electrode P1. The substrate 591 and the source layer SLL are electrically connected to each other by the via C1, the wire 519, the via 516, and the interface electrode P1.

### 1-6. Overview of Word Line Selecting Transistor (TR22)

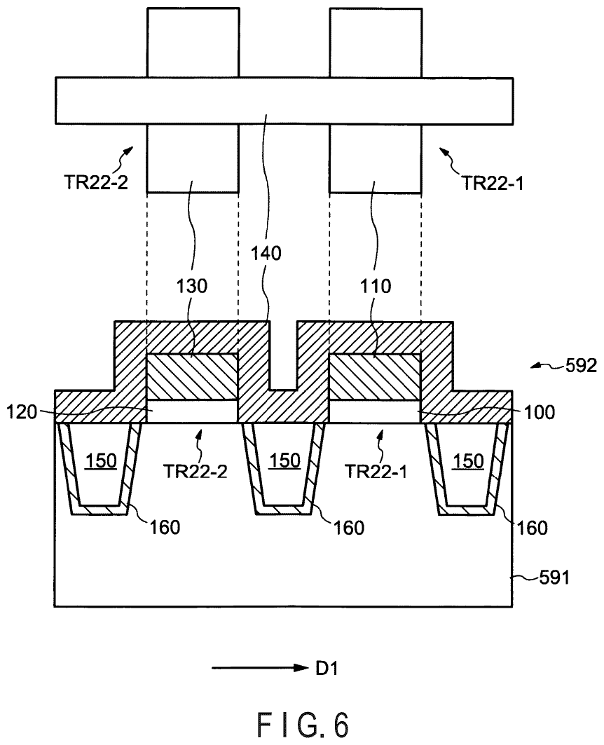

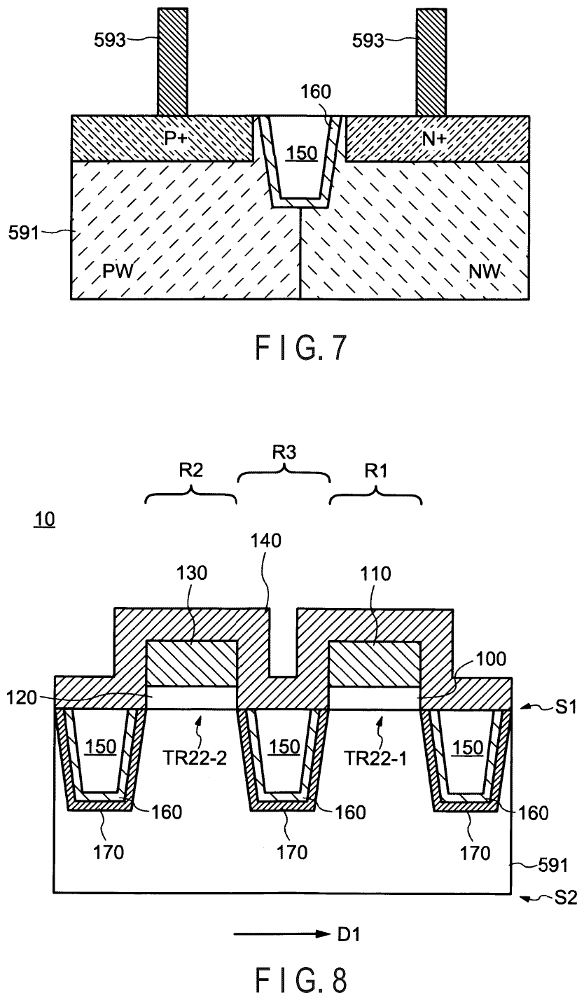

First, with reference to FIGS. 6 and 7, a detailed configuration of the word line selecting transistor will be described. FIG. 6 is a plan view and a cross-sectional view of the semiconductor device 10 according to this embodiment. As described above, the word line selecting transistor corresponds to the transistor TR22 in FIG. 4. The transistor TR22 shown in FIG. 6 is the transistor TR22 included in the block selection unit 220, which is a part of the peripheral circuit 590.

As shown in FIG. 6, transistors TR22 are provided at positions adjacent in D1 direction. When the two transistors TR22 need to be distinguished, the transistors are referred to as transistors TR22-1 and TR22-2. When the two transistors TR22 do not need to be distinguished, the transistors are referred to as the transistors TR22. The transistor TR22 is a transistor that includes a part of the substrate 591, which is a semiconductor, as a channel. The transistor TR22-1 includes a gate insulating layer 100 and a gate electrode 110. The transistor TR22-2 includes a gate insulating layer 120 and a gate electrode 130. A gate wire 140 is provided on the gate electrodes 110 and 130. The gate wire 140 extends across the gate electrodes 110 and 130 in D1 direction. With this configuration, a common voltage is applied to the gate electrodes of a plurality of transistors TR22 arranged side by side in D1 direction.

A groove (hereinafter referred to as a trench 150) is provided in the substrate 591 between the transistors TR22-1 and TR22-2. The trench 150 includes a recess formed in an upper part of the substrate 591 and an insulator provided inside the recess. An impurity region 160 is provided adjacent to the trench 150 in the substrate 591. The impurity region 160 contains a first impurity that alters the threshold voltage of the transistor TR22. When the substrate 591 is an N-type semiconductor, the first impurity is boron, for example. When the substrate 591 is a P-type semiconductor, the first impurity is phosphorus or arsenic, for example. In this embodiment, a case where the substrate 591 is an N-type semiconductor and the first impurity is boron will be described.

The transistors TR22 are arranged side by side to correspond to the word lines WL provided in the string unit SU. Therefore, as the memory cell array 510 is reduced in size and increased in capacity, the distances between the adjacent transistors TR22 decrease. As a result, the leak current between the adjacent transistors TR22 may increase.

The trench 150 and the impurity region 160 are provided to reduce the leak current between the transistors TR22-1 and TR22-2. Specifically, the trench 150 is provided to increase the effective distance between the transistors TR22-1 and TR22-2. The impurity region 160 is provided to reduce formation of an inversion layer and generation of carriers in the substrate 591 when a voltage is applied to the gate wire 140.

For example, when the substrate 591 is an N-type semiconductor, if the amount of boron in the impurity region 160 increases, the threshold voltage of the impurity region 160 is shifted in the positive direction. Therefore, compared with a case where the impurity region 160 is not provided, carriers are less likely to be generated due to the voltage supplied to the gate wire 140 in the impurity region 160. By providing the trench 150 and the impurity region 160 as described above, the leak current between the transistors TR22-1 and TR22-2 can be reduced.

Even with the configuration described above, the leak current between the transistors TR22-1 and TR22-2 may increase if the distance between the adjacent transistors TR22-1 and TR22-2 further decreases (if the distance becomes 500 nm or less, for example). The leak current can be reduced by increasing the amount of boron implanted into the impurity region 160.

When a voltage is applied to the gate wire 140, carriers caused by the electric field are mainly generated in a surface layer of the semiconductor, e.g., a surface layer of the substrate 591 that is in contact with the side wall and the bottom of the trench 150 in this embodiment. That is, in order to reduce the leak current that occurs between the transistors TR22-1 and TR22-2, the boron concentration of the surface layer of the substrate 591 that is in contact with the side wall and the bottom of the trench 150 needs to be increased. However, boron has a characteristic that boron is likely to be diffused by heat treatment, and therefore, in order to maintain the boron concentration of the surface layer of the substrate 591 at a predetermined level, the total amount of boron implanted into the impurity region 160 needs to be increased.

As described above, in order to reduce the leak current between the transistors TR22-1 and TR22-2, the total amount of boron implanted into the impurity region 160 needs to be increased. However, as the total amount of boron in the impurity region 160 is increased, a phenomenon described below may occur.

As shown in FIG. 5, the N+-diffused region DF sandwiched between the P wells PW on the opposite sides thereof is provided in a part of the peripheral circuit 590.

That is, a PN junction region in which a P well and an N well are connected exists in the substrate 591 (e.g., near or on the left side of the leftmost contact 596 in FIG. 5). FIG. 7 is a cross-sectional view of the PN junction region of the semiconductor device according to this embodiment. As shown in FIG. 7, a P well PW and an N well NW are formed in the substrate 591. A P+ region is provided on top of the P well PW. An N+ region is provided on top of the N well NW. The P+ region is a region containing a higher concentration of impurity than the P well PW. The N+ region is a region concerning a higher concentration of impurity than the N well NW. The trench 150 is provided near the boundary between the P well PW and the N well NW. As with the configuration in FIG. 6, the impurity region 160 is provided between the trench 150 and the substrate 591.

As described above, when the substrate 591 is an N-type semiconductor, boron is implanted into the impurity region 160, so that the impurity region 160 in the substrate 591 is a P-type semiconductor. Therefore, in the configuration in FIG. 7, a PN junction is formed between the P well PW and the N well NW and between the impurity region 160 and the N well NW.

If the total amount of boron contained in the impurity region 160 is increased in order to reduce the leak current that occurs between the transistors TR22-1 and TR22-2 shown in FIG. 6, the junction withstand voltage of the PN junction between the impurity region 160 and the N well NW shown in FIG. 7 deteriorates. As a result, in particular, in a region to which a high voltage is applied between the P+ region and the N+ region, a leak current due to the deterioration in withstand voltage of the PN junction described above may increase. Therefore, there is an upper limit to the total amount of boron implanted into the impurity region 160 in order to reduce the leak current that occurs between the transistors TR22-1 and TR22-2.

### Configuration of Word Line Selecting Transistor (TR22) in this Embodiment

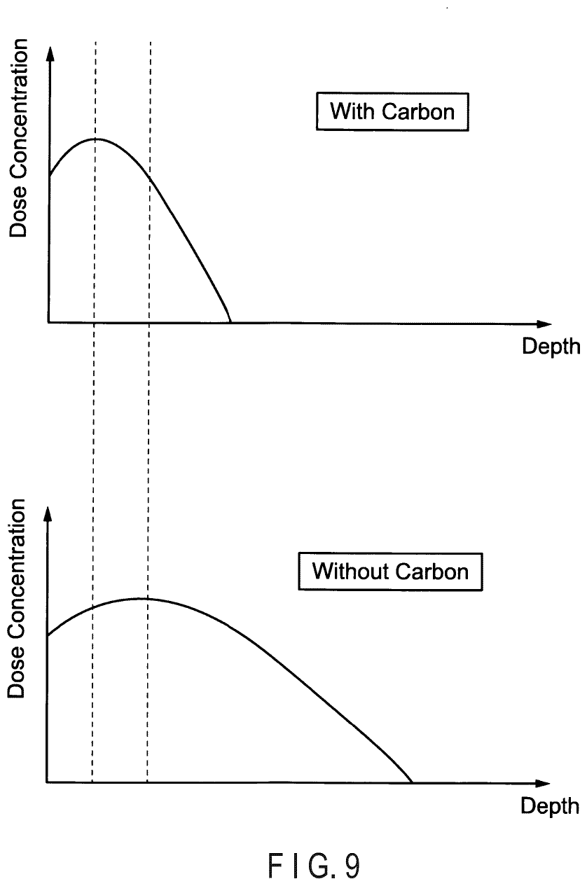

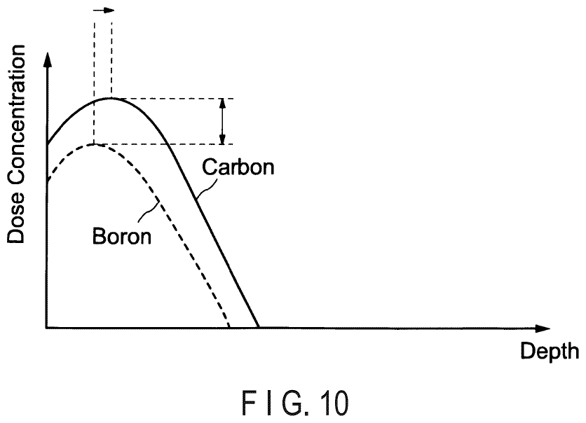

With reference to FIGS. 8 to 10, a configuration of the transistor TR22 according to this embodiment will be described. FIG. 8 is a cross-sectional view of the semiconductor device 10 according to this embodiment. FIGS. 9 and 10 show concentration profiles of the impurity implanted into the impurity region of the semiconductor device 10 according to this embodiment. The cross-sectional view of FIG. 8 is similar to the cross-sectional view of FIG. 6. In the following description, descriptions of components similar to those shown in FIG. 6 may be omitted. The transistor TR22 shown in FIG. 8 is the transistor TR22 included in the block selection unit 220, which is a part of the peripheral circuit 590.

As shown in FIG. 8, the semiconductor device 10 includes the substrate 591, the transistor TR22-1, and the transistor TR22-2. The trench 150 is provided between the transistors TR22-1 and TR22-2. The trench 150 is a groove or a recess provided in the substrate 591. The insulating layers 151 and 152 are provided in the trench 150 as shown in FIG. 16. The transistor TR22-1 is provided in a region R1. The transistor TR22-2 is provided in a region R2. The trench 150 is provided in a region R3. The region R3 is located between the regions R1 and R2 and adjacent to the regions R1 and R2. The gate wire 140 is provided above the transistor TR22-1, the transistor TR22-2 and the trench 150 and is continuous from the region R1 to the region R2.

As described above, the transistors TR22-1 and TR22-2 are adjacent to each other with the trench 150 interposed therebetween. Therefore, of the word lines WL provided in the memory cell array 510, the word line WL connected to the transistor TR22-1 and the word line WL connected to the transistor TR22-2 are adjacent to each other

On the other hand, unlike the configuration shown in FIG. 6, an impurity region 170 is provided in a part of the substrate 591 adjacent to the trench 150, in addition to the impurity region 160. The impurity region 160 contains a first impurity that alters the threshold of the transistor TR22. The impurity region 170 contains a second impurity that reduces the diffusion of the first impurity caused by heat treatment or the like. When the first impurity is boron, carbon can be used as the second impurity, for example.

The substrate 591 may be referred to as “a first substrate.” The transistor TR22-1 may be referred to as a “first transistor.” The transistor TR22-2 may be referred to as a “second transistor.” The region R1 may be referred to as a “first region.” The region R2 may be referred to as a “second region.” The region R3 may be referred to as a “third region.” The trench 150 may be referred to as a “first trench.” The gate wire 140 may be referred to as a “first conductive layer.” The impurity region 160 and the impurity region 170 may be collectively referred to as a “first impurity region.” The substrate 591 includes a first surface S1 and a second surface S2. The second surface S2 is a surface opposite to the first surface S1. The transistor TR22 is provided on the first surface S1.

In FIG. 8, for the convenience of description, the impurity region 160 containing the first impurity and the impurity region 170 containing the second impurity are shown as being provided in different regions. However, the impurity region 160 and the impurity region 170 may partially or completely overlap with each other. In FIG. 8, the impurity region 170 is provided on the outer side of the impurity region 160, when viewed from the trench 150. This means that in the impurity concentration profile, the position of a peak of the second impurity is located on the outer side than the position of a peak of the first impurity. Note that the position of the peak of the first impurity may be located on the outer side than the position of the peak of the second impurity, or the peak of the first impurity and the peak of the second impurity may coincide with each other.

The concentration profiles shown in FIG. 9 are impurity profiles in a direction from the bottom of the trench 150 toward the second surface S2 of the substrate 591. The boron concentration profiles shown in FIG. 9 are both profiles after the impurity is ion-implanted and then a thermal hysteresis equivalent to that in the manufacturing process for the semiconductor device 10 is applied. In FIG. 9, the vertical axis (Dose Concentration) indicates the concentration of the implanted impurity, and the horizontal axis (Depth) indicates the depth of the implantation of the impurity. The concentration profile (Without Carbon) shown in the lower part of FIG. 9 is a concentration profile in a case where only boron is ion-implanted into the substrate 591. The concentration profile (With Carbon) shown in the upper part of FIG. 9 is a concentration profile in a case where boron and carbon are ion-implanted into the substrate 591. As shown in FIG. 9, by ion-implanting carbon in addition to boron into the substrate 591, the diffusion of boron into the substrate 591 can be reduced even after heat treatment.

As described above, boron tends to be diffused into the substrate 591 as a result of heat treatment or the like, and carbon has a function of reducing the diffusion of boron. Therefore, by providing the impurity region 160 containing boron and the impurity region 170 containing carbon at positions adjacent to the trench 150, the diffusion of boron in the substrate 591 caused by the subsequent heat treatment or the like can be reduced after boron is ion-implanted into the substrate 591. Therefore, when implanting boron into the substrate 591 by ion implantation or other means, the total amount of boron implanted can be reduced by implanting boron under low energy conditions so that the boron concentration profile has a peak near the surface layer of the substrate 591 that is adjacent to the side wall and bottom of the trench 150.

The concentration profile shown in FIG. 10 is an impurity profile in the direction from the bottom of the trench 150 toward the second surface S2 of the substrate 591. FIG. 10 shows both a boron concentration profile and a carbon concentration profile. The peak of the carbon concentration profile is located at a deeper position (i.e., a position closer to the second surface S2) than the peak of the boron concentration profile. Furthermore, the height of the peak of the carbon concentration profile is higher than the height of the peak of the boron concentration profile. Specifically, the heights of the peaks differ by an order of magnitude or more.

In this embodiment, boron and carbon contained in the impurity regions 160 and 170 are not impurities that uniformly exist in the substrate 591. The impurities in this embodiment are implanted into the substrate 591 by ion implantation, for example. Therefore, in the concentration profile shown in FIG. 10, the carbon concentration and the boron concentration partially gradually decrease in the direction from the bottom of the trench 150 toward the second surface S2.

Although FIG. 10 shows an example in which the peak of the carbon concentration profile is located at a deeper position than the peak of the boron concentration profile, the present invention is not limited to this example. For example, the peak of the carbon concentration profile may be located at a shallower position than the peak of the boron concentration profile, or the peaks of the concentration profiles may be located at the same position. Similarly, the height of the peak of the carbon concentration profile may be lower than the height of the peak of the boron concentration profile, and the heights of the peaks of the concentration profiles may be the same.

As described above, with the semiconductor device 10 according to this embodiment, the impurity region 160 between the trench 150 and the substrate 591 contains the first impurity (i.e., boron) that alters the threshold of the transistor TR22 and the second impurity (i.e., carbon) that reduces the diffusion of the first impurity due to heat treatment or the like, and therefore, the first impurity can be concentrated in the vicinity of the surface layer of the substrate 591 adjacent to the side wall and the bottom of the trench 150 while reducing the total amount of the first impurity implanted into the impurity region 160. As a result, the leak current between the adjacent transistors TR22 can be reduced, and at the same time, the deterioration of the withstand voltage of the PN junction can be reduced.

### 1-8. Variations

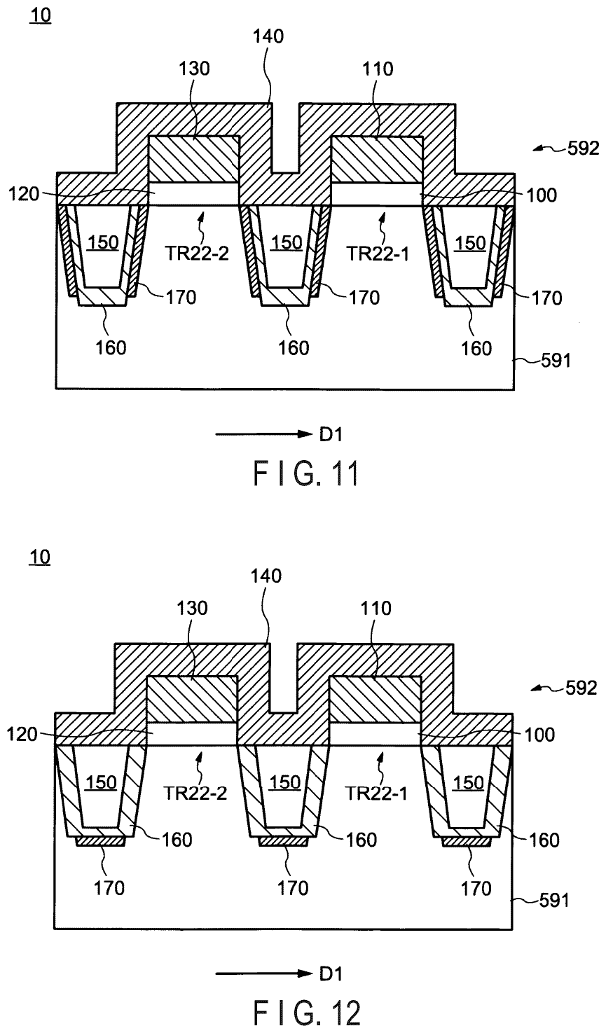

With reference to FIGS. 11 and 12, variations of the first embodiment will be described.

FIGS. 11 and 12 are cross-sectional views of semiconductor devices 10 according to variations of the above-described embodiment. The configurations shown in FIGS. 11 and 12 are similar to the configuration shown in FIG. 8 but differ from the configuration shown in FIG. 8 in position of the impurity region 170 containing carbon.

Specifically, in the configuration shown in FIG. 11, although the impurity region 170 is provided at a position corresponding to the side wall of the trench 150, the impurity region 170 is not provided at a position corresponding to the bottom of the trench 150. In the configuration shown in FIG. 11, since the impurity region 170 is not provided at a position corresponding to the bottom of the trench 150, the diffusion of boron is not reduced at the bottom of the trench 150. As a result, the width of the impurity region 160 at the bottom of the trench 150 is greater than the width of the impurity region 160 at the side wall of the trench 150. Note that the width of the impurity region 160 means a range in which boron exists. More specifically, the width of the impurity region 160 means the width of the region in which the concentration of boron is 1E13/cm3 or more in the concentration profile. However, the width of the impurity region 160 may be the width of a region in which the concentration of boron is equal to or more than 1E14/cm3 or is equal to or more than 1E15/cm3 in the concentration profile.

On the other hand, in the configuration shown in FIG. 12, although the impurity region 170 is provided at a position corresponding to the bottom of the trench 150, the impurity region 170 is not provided at a position corresponding to the side wall of the trench 150. In the configuration shown in FIG. 12, since the impurity region 170 is not provided at a position corresponding to the side wall of the trench 150, the diffusion of boron is not reduced at the side wall of the trench 150. As a result, the width of the impurity region 160 at the side wall of the trench 150 is greater than the width of the impurity region 160 at the bottom of the trench 150.

As shown in the variations described above, the impurity region 170 need not be provided along the whole of the side wall and the bottom of the trench 150, and can be provided so as to block the path of the leak current between the transistors TR22-1 and TR22-2.

### 1-9. Manufacturing Method

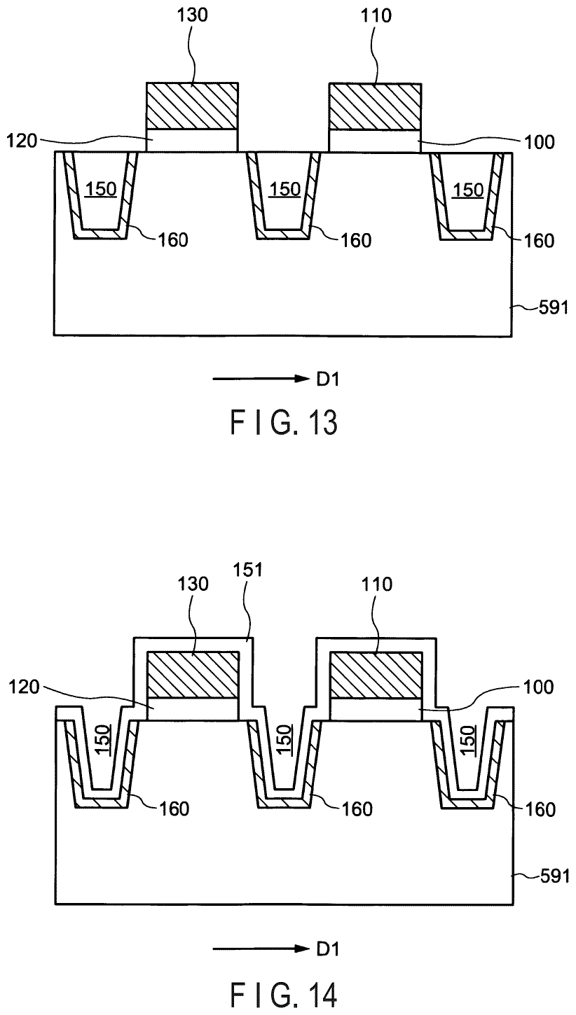

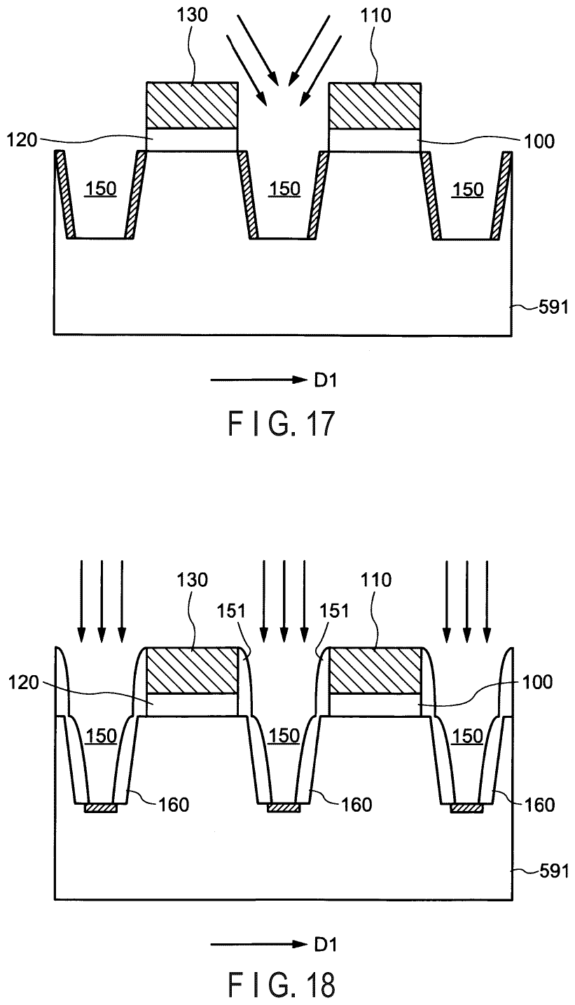

With reference to FIGS. 13 to 18, a manufacturing method for the configurations according to the first embodiment and variations thereof will be described. FIGS. 13 to 18 are cross-sectional views for illustrating a manufacturing method for the semiconductor devices 10 according to the embodiment and variations thereof. First, with reference to FIGS. 13 to 16, a method of forming the trench 150 and the impurity region 160 will be described. A timing for forming the impurity region 170 in the first embodiment will then be described. Furthermore, timings for forming the impurity region 170 in the variations will be described with reference to FIGS. 17 and 18, respectively.

As shown in FIG. 13, after the gate insulating layers 100 and 120 and the gate electrodes 110 and 130 are formed on the substrate 591, the top part of the substrate 591 is etched in a region exposed outside of the gate electrodes 110 and 130, thereby forming the trench 150. The trench 150 may be formed by using the gate electrodes 110 and 130 as masks or may be formed by using a separately prepared resist as a mask. In the state where the side wall and the bottom of the trench 150 are exposed, boron is implanted to form the impurity region 160.

As shown in FIG. 14, the insulating layer 151 is then formed on the gate electrodes 110 and 130 and inside the trench 150. The insulating layer 151 is formed in a deposition method having isotropy. The insulating layer 151 is formed by chemical vapor deposition (CVD), for example. As the insulating layer 151, a silicon oxide layer is formed, for example. Note that another insulating layer may be formed as the insulating layer 151.

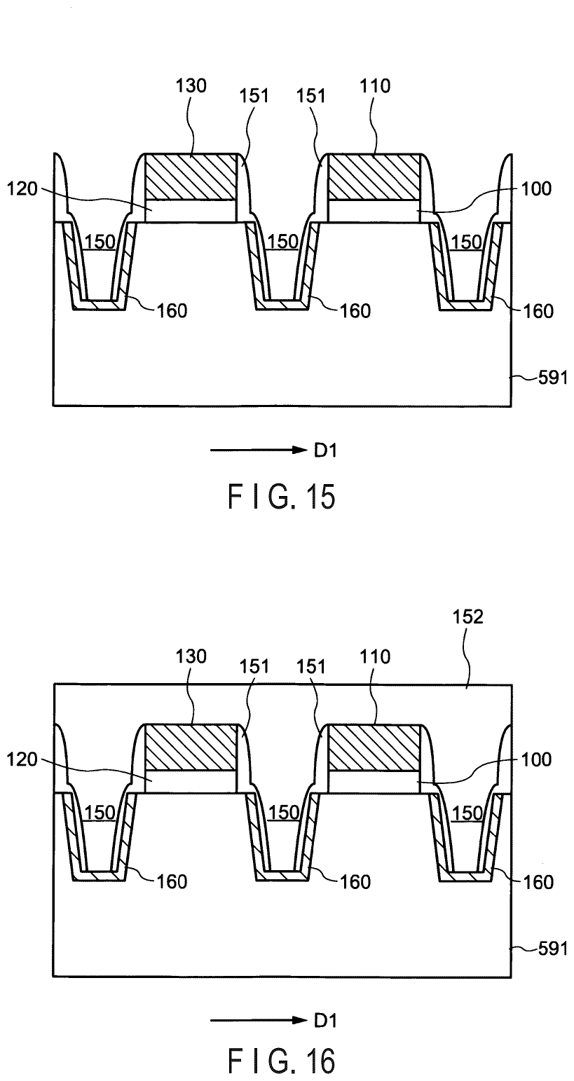

As shown in FIG. 15, the insulating layer 151 is then subjected to anisotropic etching. In the etching, the insulating layer 151 is mainly etched from above, and therefore, the insulating layer 151 is removed from the top surfaces of the gate electrodes 110 and 130 and the bottom of the trench 150, while the insulating layer 151 partially remains on the side walls of the gate electrodes 110 and 130 and the side wall of the trench 150 where the insulating layer 151 is formed thicker when viewed from above.

As shown in FIG. 16, the insulating layer 152 is then formed on the gate electrodes 110 and 130 and inside the trench 150. The insulating layer 152 is formed by a deposition method having isotropy. For example, the insulating layer 152 is formed by CVD, as with the insulating layer 151. After that, the insulating layer 152 is etched to expose the gate electrodes 110 and 130, and then the gate wire 140 is formed. In this way, the structures of the trench 150 and the impurity region 160 shown in FIGS. 8, 11, and 12 are formed. Note that the position at which the impurity region 170 is formed can be adjusted by changing the timing of carbon implantation in the manufacturing method described here.

When forming the impurity region 170 in a region corresponding to the side wall and the bottom of the trench 150 as shown in FIG. 8, as shown in FIG. 13, after the trench 150 is formed in the substrate 591 and before the insulating layer 151 is formed, carbon implantation is performed in the state where the side wall and the bottom of the trench 150 are exposed. Note that carbon may be implanted after boron is implanted, or boron may be implanted after carbon is implanted.

When forming the impurity region 170 on the side wall of the trench 150 but not forming the impurity region 170 on the bottom of the trench 150 as shown in FIG. 11, as shown in FIG. 17, after the trench 150 is formed in the substrate 591 and before the insulating layer 151 is formed, carbon implantation is performed in a slanting direction with respect to the substrate 591 in the state where the side wall and the bottom of the trench 150 are exposed. Noe that the slanting direction means a direction slanting with respect to the normal to the principal surface of the substrate 591. As with the case described above, carbon may be implanted after boron is implanted, or boron may be implanted after carbon is implanted.

When forming the impurity region 170 on the bottom of the trench 150 but not forming the impurity region 170 on the side wall of the trench 150 as shown in FIG. 12, as shown in FIG. 18, carbon implantation is performed in the state where the insulating layer 151 formed remains on the side walls of the gate electrodes 110 and 130 and the side wall of the trench 150, and the substrate 591 is exposed at the bottom of the trench 150. In this case, since the impurity region 160 is already formed, carbon is implanted after boron is implanted.

The variations of the first embodiment can provide the same effects as those of the first embodiment.

### 2. Second Embodiment

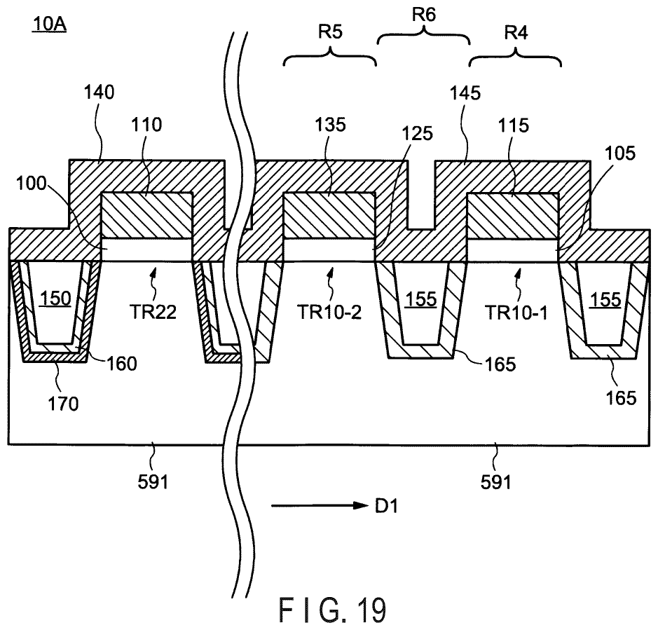

With reference to FIG. 19, a semiconductor device 10A according to a second embodiment will be described. Although the semiconductor device 10A according to the second embodiment is similar to the semiconductor device 10 according to the first embodiment, the semiconductor device 10A differs from the semiconductor device 10 according to the first embodiment in that not only a region in which the impurity regions 160 and 170 are formed at positions adjacent to the trench 150 but also a region in which only an impurity region 165 is formed at a position adjacent to a trench 155 and the impurity region 170 is not formed are provided on the same substrate 591.

As shown in FIG. 19, transistors TR22 and transistors TR10 (TR10-1 and TR10-2) are provided on the substrate 591. The transistors TR22 are the same as the transistors TR22 shown in FIG. 8 and therefore will not be described here. The transistor TR10-1 and the transistor TR10-2 are adjacent to each other in D1 direction with the trench 155 interposed therebetween. When the two transistors TR10 need to be distinguished, the transistors are referred to as the transistors TR10-1 and TR10-2, respectively, and when the two transistors TR10 do not need to be distinguished, the two transistors are referred to as the transistors TR10.

The transistor TR10 is a transistor that includes a part of the substrate 591, which is a semiconductor, as a channel. The transistor TR10-1 includes a gate insulating layer 105 and a gate electrode 115. The transistor TR10-2 includes a gate insulating layer 125 and a gate electrode 135. A gate wire 145 is provided on the gate electrodes 115 and 135. The gate wire 145 extends across the gate electrodes 115 and 135 in the D1 direction. With this configuration, a common voltage is applied to the gate electrodes of a plurality of transistors TR10 arranged side by side.

A groove (hereinafter referred to as a trench 155) is provided in the substrate 591 between the transistors TR10-1 and TR10-2. The trench 155 includes a recess formed in an upper part of the substrate 591 and an insulator provided inside the recess. An impurity region 165 is provided adjacent to the trench 155 in the substrate 591. The impurity region 165 contains a first impurity that alters the threshold of the transistor TR10. When the substrate 591 is an N-type semiconductor, the first impurity is boron, for example. When the substrate 591 is a P-type semiconductor, the first impurity is phosphorus or arsenic, for example.

The transistor TR10 differs from the transistor TR22 in that the impurity region 165 is formed in the trench 155 and the impurity region 170 is not formed. That is, the second impurity (carbon, for example) is not intentionally implanted into the impurity region 165. Therefore, the concentration of the second impurity contained in the impurity region 165 is equal to or less than 1E13/cm3. However, the concentration of the second impurity contained in the impurity region 165 may be equal to or less than 1E14/cm3 or may be equal to or less than 1E15/cm3. Note that since the transistors TR22 and the transistors TR10 are formed on the same substrate 591, the trench 150 and the trench 155 are subjected to the same heat treatment. Therefore, the impurity region 165 adjacent to the trench 155 is more susceptible to thermal diffusion than the impurity region 160 adjacent to the trench 150. As a result, the width of the impurity region 165 is greater than the width of the impurity region 160.

The configuration described above can be formed by covering the trench 155 adjacent to the transistors TR10 with a mask when implanting carbon to form the impurity region 170. For example, the configuration described above can be formed by implanting carbon by using a mask having an opening in a part where the diffusion of boron in the impurity region 160 is required to be reduced.

The transistor TR10-1 may be referred to as a “third transistor.” The transistor TR10-2 may be referred to as a “fourth transistor.” A region R4 may be referred to as a “fourth region.” A region R5 may be referred to as a “fifth region.” A region R6 may be referred to as a “sixth region.” The trench 155 may be referred to as a “second trench.” The gate wire 145 may be referred to as a “second conductive layer.” The impurity region 165 may be referred to as a “second impurity region.”

As described above, with the semiconductor device 10A according to this embodiment, the same configuration as the configuration according to the first embodiment can be formed only in a region where the configuration is required to be formed.

### 3. Third Embodiment

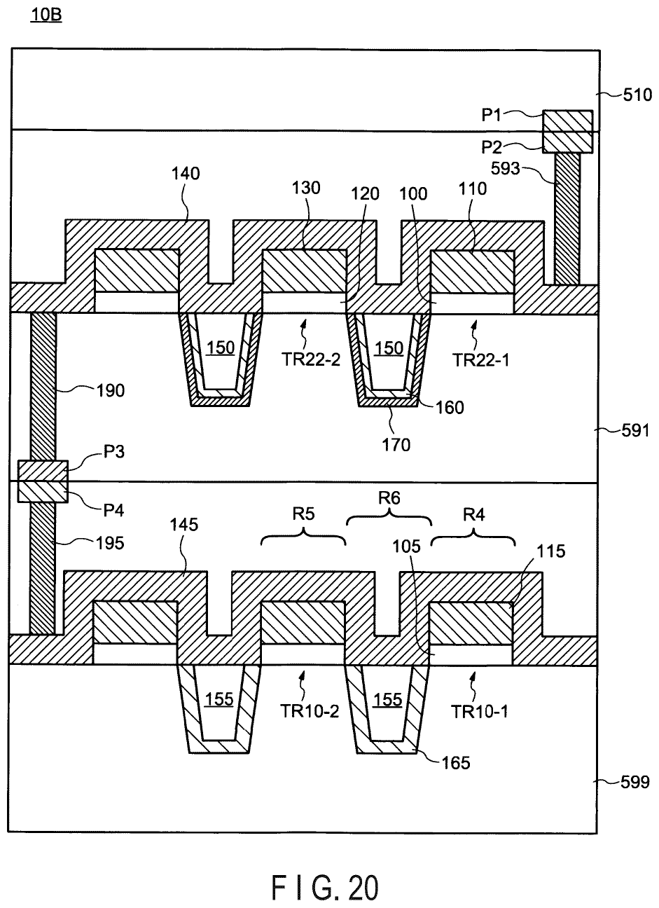

With reference to FIG. 20, a semiconductor device 10B according to a third embodiment will be described. Although the semiconductor device 10B according to the third embodiment is similar to the semiconductor device 10A according to the second embodiment, the semiconductor device 10B differs from the semiconductor device 10A according to the second embodiment in that the substrate 591 including the impurity regions 160 and 170 formed in the trench 150 and a substrate 599 having the impurity region 165 formed in the trench 155 are stacked on one another. The transistor TR22 shown in FIG. 20 is the transistor TR22 included in the block selection unit 220, which is a part of the peripheral circuit. The transistor TR10 is a transistor included in a circuit that is another part of the peripheral circuit.

As shown in FIG. 20, the semiconductor device 10B according to this embodiment has a configuration in which the substrates 591 and 599 and the memory cell array 510 are stacked on one another. The relationship between the substrate 591 and the memory cell array 510 is the same as the relationship shown in FIG. 5. That is, the gate wire 140 provided on the substrate 591 is connected to the interface electrode P2 via the via 593, and the interface electrode P2 is connected to the interface electrode P1 provided on the memory cell array 510. An interface electrode P3 is provided on a lower surface of the substrate 591, and the gate wire 140 and the interface electrode P3 are connected to each other by a through electrode 190 that penetrates through the substrate 591.

The transistor TR22 is the same as the transistor TR22 shown in FIG. 8 and therefore will not be described here. The transistor TR10 is the same as the transistor TR10 shown in FIG. 19 and therefore will not be described here. In the substrate 591, as with the configuration in FIG. 8, the impurity regions 160 and 170 are formed in the trench 150 between the adjacent transistors TR22. On the other hand, in the substrate 599, the impurity region 165 is formed in the trench 155 between the adjacent transistors TR10, and the impurity region 170 is not formed.

A via 195 is formed on the gate wire 145 near an end of the substrate 599. The via 195 is connected to an interface electrode P4, and the interface electrode P4 is connected to the interface electrode P3.

This configuration can be formed by forming transistors for which the diffusion of boron in the impurity region 160 is required to be reduced on the substrate 591, forming the other transistors on the substrate 599, and connecting the substrates 591 and 599 to each other at the interface electrodes P3 and P4 as described above.

The substrate 599 may be referred to as a “second substrate.” The circuit in which the transistors TR10 are provided may be referred to as a “second peripheral circuit.” That is, the second peripheral circuit includes the transistor TR10-1 (i.e., the third transistor) provided in the region R4 (i.e., the fourth region), the transistor TR10-2 (i.e., the fourth transistor) provided in the region R5 (i.e., the fifth region), the trench 155 (i.e., the second trench) provided in the substrate 599 (i.e., the second substrate) in the region R6 (i.e., the sixth region), the gate wire 145 (i.e., the second conductive layer) that is provided above the transistor TR10-1 (third transistor), the transistor TR10-2 (i.e., the fourth transistor) and the trench 155 (i.e., the second trench) and is continuous from the region R4 (i.e., the fourth region) to the region R5 (i.e., the fifth region), and the impurity region 165 (i.e., the second impurity region) provided adjacent to the trench 155 (i.e., the second trench) in the substrate 599 (i.e., the second substrate).

As described above, with the semiconductor device 10B according to this embodiment, the same configuration as the configuration according to the first embodiment can be applied only to a transistor that requires the configuration.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

Of course, other advantageous effects than the advantageous effects provided by the aspects of the embodiments described above should be understood as being provided by the present invention as far as they are obvious from the description in this specification or can be easily predicted by those skilled in the art.

What is claimed is:

1. A semiconductor device comprising:
a first substrate that includes a plurality of regions including a first region, a second region, and a third region between the first and second regions;
a first transistor in the first region;
a second transistor in the second region;
a first trench in the third region;
a first conductive layer that continuously covers the first transistor, the first trench, and the second transistor; and
an impurity region that is adjacent to the first trench in the first substrate and includes carbon.

2. The semiconductor device according to claim 1, wherein the impurity region further includes boron.

3. The semiconductor device according to claim 2, wherein
the first substrate has a first surface along which the first and second transistors and the first trench are arranged and a second surface that is opposite to the first surface, and
concentrations of carbon and boron in a part of the impurity region gradually decrease in a first direction from a bottom surface of the first trench towards the second surface of the first substrate.

4. The semiconductor device according to claim 3, wherein a part of the impurity region including a greatest concentration of carbon is closer to the second surface of the first substrate than another part of the impurity region including a greatest concentration of boron in the first direction.

5. The semiconductor device according to claim 4, wherein the greatest concentration of carbon is at least 10 times greater than the greatest concentration of boron.

6. The semiconductor device according to claim 2, wherein the impurity region includes:
a first impurity region that includes boron and surrounds the first trench, and
a second impurity region that includes carbon and is adjacent to the first impurity region.

7. The semiconductor device according to claim 6, wherein
the second impurity region extends along a side wall of the first trench, and
a thickness of a part of the first impurity region below a bottom surface of the first trench is greater than a thickness of another part of the first impurity region between the side wall of the first trench and the second impurity region.

8. The semiconductor device according to claim 6, wherein
the second impurity region extends along a bottom surface of the first trench, and
a thickness of a part of the first impurity region between the bottom surface of the first trench and the second impurity region is smaller than a thickness of another part of the first impurity region extending along a side wall of the first trench.

9. The semiconductor device according to claim 1, wherein
the plurality of regions of the first substrate further includes a fourth region, a fifth region, and a sixth region between the fourth and fifth regions,
the semiconductor device further comprises:
a third transistor in the fourth region;
a fourth transistor in the fifth region;
a second trench in the sixth region;
a second conductive layer that continuously covers the third transistor, the second trench, and the fourth transistor; and
another impurity region adjacent to the second trench in the first substrate, and
a concentration of carbon in said another impurity region is equal to or less than 1E13/cm3.

10. The semiconductor device according to claim 1, wherein
the plurality of regions of the first substrate further includes a seventh region, an eighth region, and ninth region between the seventh and eighth regions,
the semiconductor device further comprises:
a first wire in the seventh region;
a second wire in the eighth region;
a third trench in the ninth region; and
another impurity region adjacent to the third trench in the first substrate, and
a concentration of carbon in said another impurity region is equal to or less than 1E13/cm3.

11. A semiconductor storage device comprising:
a first substrate that includes a plurality of regions including a first region, a second region, and a third region between the first and second regions;
a memory cell array that includes a plurality of word lines including a first word line and a second word line adjacent to the first word line;
a first peripheral circuit that is on the first substrate and configured to drive the memory cell array, the first peripheral circuit including:
a first transistor disposed in the first region and electrically connected to the first word line, and
a second transistor disposed in the second region and electrically connected to the second word line;
a first trench in the third region;
a first conductive layer that continuously covers the first transistor, the first trench, and the second transistor; and
an impurity region that is adjacent to the first trench and includes carbon.

12. The semiconductor storage device according to claim 11, further comprising:
a second substrate that includes another plurality of regions including a fourth region, a fifth region, and a sixth region between the fourth and fifth regions;
a second peripheral circuit that is on the second substrate and electrically connected to the memory cell array, the second peripheral circuit including:
a third transistor in the fourth region, and
a fourth transistor in the fifth region;
a second trench in the sixth region;
a second conductive layer that continuously covers the third transistor, the second trench, and the fourth transistor; and
another impurity region adjacent to the second trench.

13. The semiconductor storage device according to claim 12, further comprising:
an electrode disposed between the first and second substrates and through which the first and second conductive layers are electrically connected.

14. The semiconductor storage device according to claim 11, wherein the impurity region further includes boron.

15. The semiconductor storage device according to claim 14, wherein
the first substrate has a first surface along which the first and second transistors and the first trench are arranged and a second surface that is opposite to the first surface, and
concentrations of carbon and boron in a part of the impurity region gradually decrease in a first direction from a bottom surface of the first trench towards the second surface of the first substrate.

16. The semiconductor storage device according to claim 15, wherein a part of the impurity region including a greatest concentration of carbon is closer to the second surface of the first substrate than another part of the impurity region including a greatest concentration of boron in the first direction.

17. The semiconductor storage device according to claim 16, wherein the greatest concentration of carbon is at least 10 times greater than the greatest concentration of boron.

18. The semiconductor storage device according to claim 14, wherein the impurity region includes:
a first impurity region that includes boron and surrounds the first trench, and
a second impurity region that includes carbon and is adjacent to the first impurity region.

19. The semiconductor storage device according to claim 18, wherein
the second impurity region extends along a side wall of the first trench, and
a thickness of a part of the first impurity region below a bottom surface of the first trench is greater than a thickness of another part of the first impurity region between the side wall of the first trench and the second impurity region.

20. The semiconductor storage device according to claim 11, wherein
the plurality of regions of the first substrate further includes a seventh region, an eighth region, and ninth region between the seventh and eighth regions,
the semiconductor storage device further comprises:
a first wire in the seventh region;
a second wire in the eighth region;
a third trench in the ninth region; and
another impurity region adjacent to the third trench in the first substrate, and
a concentration of carbon in said another impurity region is equal to or less than 1E13/cm3.
